(19) United States
(12) Patent Application Publication
(10) Pub. No.: US 2007/0252207 A1
(43) Pub. Date: Nov. 1, 2007

(54) Thin film transistor and method of fabricating the same

(75) Inventors: Jae-Chul Park, Seoul (KR); Young-Soo Park, Suwon-si (KR); Young-Kwan Cha, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/706,316

(22) Filed: Feb. 15, 2007

(30) Foreign Application Priority Data
Apr. 27, 2006 (KR) 10-2006-0038334

(51) Int. Cl. H01L 29/786; H01L 21/336

(52) U.S. Cl. 257/347; 438/151; 257/E29.273; 257/E21.409

(57) ABSTRACT

A thin film transistor (TFT) and a method of fabricating the TFT may be provided. The TFT may include a substrate; a channel formed on the substrate; source and drain layers formed on both ends of the channel; a gate insulator covering the source and drain layers and the channel; a gate formed on the gate insulator; an ILD (interlayer dielectric) layer covering the gate; and/or source and drain electrodes contacting the source and drain layers through contact holes formed in the ILD layer and the gate insulator.

### PRIORITY STATEMENT

This application claims the benefit of priority to Korean Patent Application No. 10-2006-0038334, filed on Apr. 27, 2006, in the Korean Intellectual Property Office, the entire contents of which is incorporated herein in its entirety by reference.

### BACKGROUND

1. Field

Example embodiments relate to a thin film transistor (TFT), and for example, to a TFT and a method of fabricating the TFT that effectively reduces defects occurring in a fabrication process.

2. Description of Related Art

Active matrix (AM) type displays using organic light emitting diodes (OLEDs) may include switching transistors and/or driving transistors. The switching transistors may require lower off-current leakage characteristics, while the driving transistors may require higher mobility characteristics.

Studies have been made to reduce off-current in polycrystalline silicon TFTs having higher mobility. A conventional method for reducing off-current may be to use lightly doped drains (LDDs) or off-set structures.

A TFT implemented in an OLED may include a polycrystalline silicon channel and a source and drain having additional ohmic layers. The TFT may have a top gate structure as shown in FIG. 1. FIG. 1 is a cross-sectional view of a portion of a conventional driving transistor driving an OLED display and an OLED connected to the driving transistor.

Referring to FIG. 1, a buffer layer 11 may be formed on a substrate 10, and a channel 12 may be formed of polycrystalline silicon in an island shape on the buffer layer 11. Source and drain ohmic layers 13s and 13d may be formed of doped silicon layers on both ends of the channel 12, and source and drain electrodes 14s and 14d may be formed of a metal material on the source and drain ohmic layers 13s and 13d. A gate insulator 15 may be formed on the resultant stack structure, and a gate 16 may be formed on the gate insulator 15 between the source and drain electrodes 14s and 14d. A passivation layer 17 may be formed of an insulating material to cover the gate 16, and an electrode 18 which may be an element of the OLED may be formed on the passivation layer 17 to be electrically connected to the drain electrode 14d.

Structural disadvantages of the conventional transistor used for the OLED may be that the source and drain ohmic layers 13s and 13d each form a stack structure together with the source and drain electrodes 14s and 14d. Step coverage of the stack structure may be poorer and the gate insulator 15 formed on the stack structure may be cracked. The poorer step coverage may be solved by a thicker gate insulator 15. However, characteristics of the conventional TFT may be deteriorated by an increase in the thickness of the gate insulator 15. An echant may permeate into the source and drain electrodes 14s and 14d on the source and drain ohmic layers 13s and 13d through the cracked part of the gate insulator 15 during patterning of the gate 16 and damage the source and drain electrodes 14s and 14d. If a cleaning solution dissolves a material of which the source and drain electrodes 14s and 14d may be formed during cleaning of a surface of the channel 12, the source and drain electrodes 14s and 14d may be polluted by the cleaning solution. Accordingly, an interface of the channel 12 may be deteriorated.

### SUMMARY

Example embodiments may provide a TFT and a method of fabricating the TFT by which pollution of metal electrodes formed on ohmic layers may be reduced.

Example embodiments may provide a TFT and a method of fabricating the TFT by which poorer step coverage caused by a stack structure underneath a gate insulator may be improved.

Example embodiments may provide a TFT including stack structures having improved interface characteristics and a method of fabricating the TFT.

According to an example embodiment, a thin film transistor (TFT) may include a substrate, a channel formed on the substrate, source and drain layers formed on both ends of the channel, a gate insulator covering the source and drain layers and the channel, a gate formed on the gate insulator, an interlayer dielectric ILD layer covering the gate, and/or source and drain electrodes contacting the source and drain layers through contact holes formed in the ILD layer and/or the gate insulator.

According to an example embodiment, the source and drain layers may be source and drain ohmic layers.

According to an example embodiment, the TFT may further include a passivation layer covering the source and drain electrodes.

According to an example embodiment, an oxide layer may be formed on a surface of the channel.

According to an example embodiment, both end portions of the channel contacting the source and drain layers may be thicker than a central portion of the channel.

According to an example embodiment, the TFT may further include a buffer layer formed between the substrate and the channel.

According to an example embodiment, the TFT may further include an electrode contacting the drain electrode through a via hole formed in the passivation layer.

According to an example embodiment, a method of fabricating a TFT may include forming a silicon channel material layer and/or a silicon ohmic material layer on a substrate, patterning the silicon channel material layer and/or the silicon ohmic material layer to form a silicon channel and/or source and drain ohmic layers contacting both ends of the silicon channel, forming a gate insulator covering the source and drain ohmic layers, forming a gate corresponding to the silicon channel on the gate insulator, forming an ILD layer on the gate insulator to cover the gate, forming contact holes in the ILD layer and/or the gate insulator on the source and drain ohmic layers, forming source and drain electrodes respectively contacting the source and drain ohmic layers through the contact holes, and/or forming a passivation layer covering the source and/or drain electrodes on the ILD layer.

According to an example embodiment, forming the silicon channel material layer and the silicon ohmic material layer may be done sequentially.

According to an example embodiment, patterning the silicon channel material layer and the silicon ohmic material layer may include forming a photoresist mask on the silicon ohmic material layer, the photoresist mask including first portions corresponding to the source and drain ohmic layers and/or a second portion positioned between the source and drain ohmic layers, wherein the second portion may be thinner than the first portions; removing portions of the silicon ohmic material layer and/or a portion of the silicon channel material layer that may not be covered with the photoresist mask; ashing an entire surface of the photoresist mask at least by a thickness corresponding to the second portion of the photoresist mask to remove the second portion of the photoresist mask; removing a portion of the silicon ohmic material layer that may not be covered with the first portions of the photoresist mask; and/or removing the photoresist mask.

According to an example embodiment, the photoresist mask including the first and/or second portions may be formed using a photolithographic method using a slit mask or a half tone mask.

According to an example embodiment, the method may further include polycrystallizing the silicon channel material layer using solid phase crystallization SPC before the silicon channel and/or the source and drain ohmic layers contacting both ends of the silicon channel may be formed. The SPC may be performed using rapid thermal annealing RTA.

According to an example embodiment, the method may further include forming an oxide layer on a surface of the silicon channel using thermal oxidization after the source and drain ohmic layers may be formed.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1 is a schematic cross-sectional view of a conventional top gate type TFT;

FIG. 2 is a schematic cross-sectional view of a TFT according to an example embodiment;

FIG. 3 is a cross-sectional view of a portion of a TFT according to an example embodiment; and

FIGS. 4A through 4P are cross-sectional views illustrating a method of fabricating a TFT according to an example embodiment.

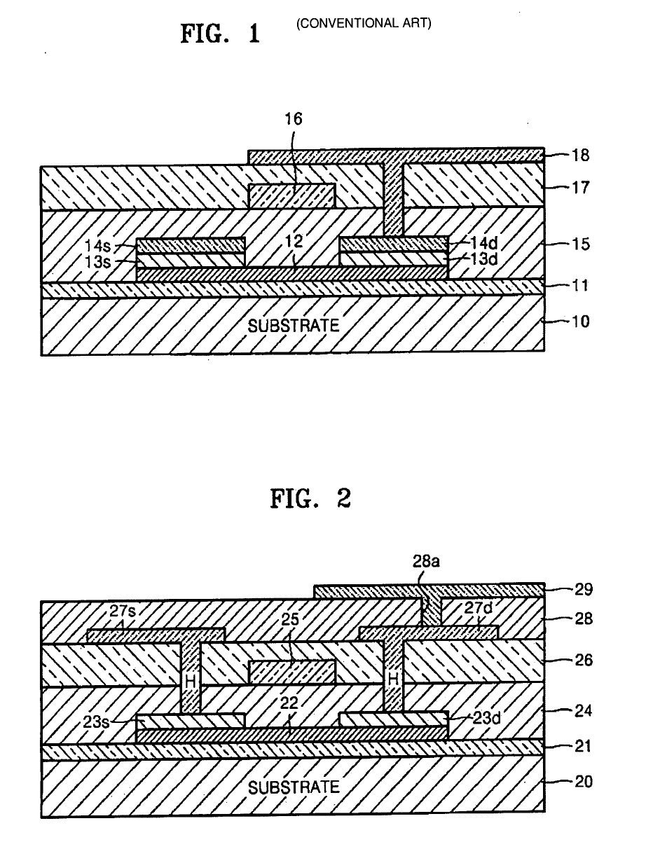

### DETAILED DESCRIPTION OF EXAMPLE EMBODIMENTS

Example embodiments will now be described more fully hereinafter with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

FIG. 2 is a schematic cross-sectional view of a polycrystalline silicon TFT implemented in an OLED according to an example embodiment. Referring to FIG. 2, a buffer layer 21 may be formed on a substrate 20, and a channel 22 may be formed of polycrystalline silicon in an island shape on the buffer layer 21. The buffer layer 21 may have a single silicon oxide layer structure or a dual layer structure of a silicon oxide layer and a silicon nitrogen oxide layer.

Source and drain ohmic layers 23s and 23d may be formed of doped silicon layers on both ends of the channel 22. The source and drain ohmic layers 23s and 23d may be patterned with the channel 22, and outer edges of the source and drain ohmic layers 23s and 24d, but not the inner edges that face each other, may coincide with outer edges of the channel 22.

A gate insulator 24 and/or a gate 25 may be formed on the source and drain ohmic layers 23s and 23d. The gate insulator 24 and the gate 25 may be sequentially formed on the source and drain ohmic layers 23s and 23d. The gate 25 may be between the source and drain ohmic layers 23s and 23d. An interlayer dielectric (ILD) layer 26 may be formed on the gate 25, and source and drain electrodes 27s and 27d may be formed on the ILD layer 26. The source and drain electrodes 27s and 27d, respectively, may contact the source and drain ohmic layers 23s and 23d through contact holes H penetrating the ILD layer 26 and/or the gate insulator 24.

A passivation layer 28 may be formed on the ILD layer 26 to cover the source and drain electrodes 27s and 27d. An electrode 29 which may be an element of the OLED may be formed on the passivation layer 28 to contact the drain electrode 27d through a via hole 28a formed in the passivation layer 28.

A TFT of example embodiments having the above-described structure may be characterized in that source and drain ohmic layers 23s and 23d formed of silicon layers may be separated from source and drain electrodes 27s and 27d. The source and drain electrodes 27s and 27d may be above the source and drain ohmic layers 23s and 23d, a gate insulator 24, and/or an ILD layer 26. Accordingly, a stack structure underneath the gate insulator 24 may become thinner, and step coverage of the gate insulator 24 may be improved.

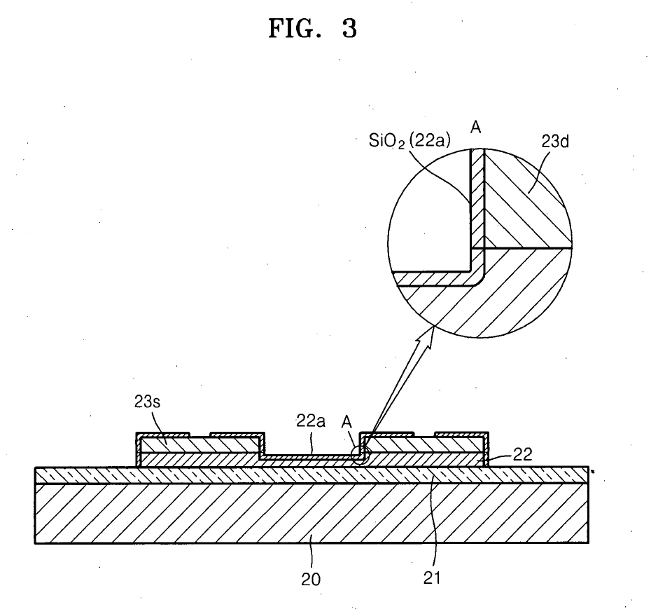

FIG. 3 is a cross-sectional view of a portion of a TFT according to another example embodiment. Referring to FIG. 3, a silicon oxide layer 22a may be formed on a surface of a channel 22 using thermal oxidization. A central portion of the channel 22 may be thinner than portions of the channel 22 underneath source and drain ohmic layers 23s and 23d. A portion at the center of the surface of the channel 22 which may not be covered with the source and drain ohmic layers 23s and 23d may be etched during forming and patterning of the source and drain ohmic layers 23s and 23d. The surface of the central portion of the channel 22 may be overetched, for example etched to completely remove a silicon ohmic material remaining on the surface of the channel 22, so as to reduce short-circuits between the source and drain ohmic layers 23s and 23d. The overetched portion of the channel 22 may be formed using an additional etching process during patterning of the source and drain ohmic layers 23s and 23d. The overetched portion of the channel 22 may be selectively applied. The silicon oxide layer 22a formed on the surface of the channel 22 using the thermal oxidization may contribute to improving an interface characteristic, for example a reduction in an interface trap density between a gate insulator 24 and the channel 22. The silicon oxide layer 22a may be selectively formed and applied.

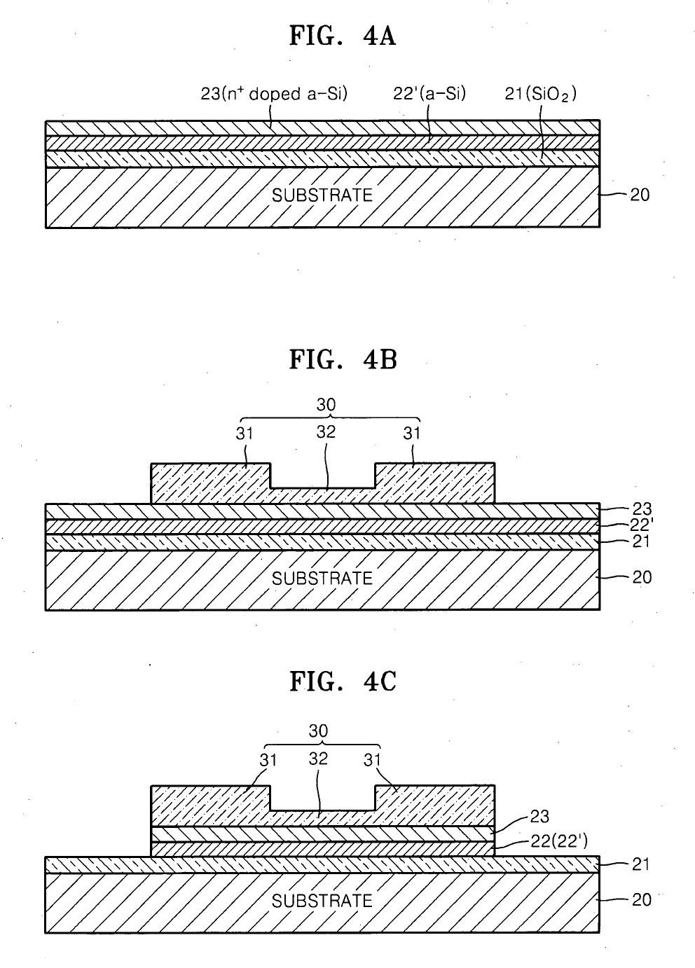

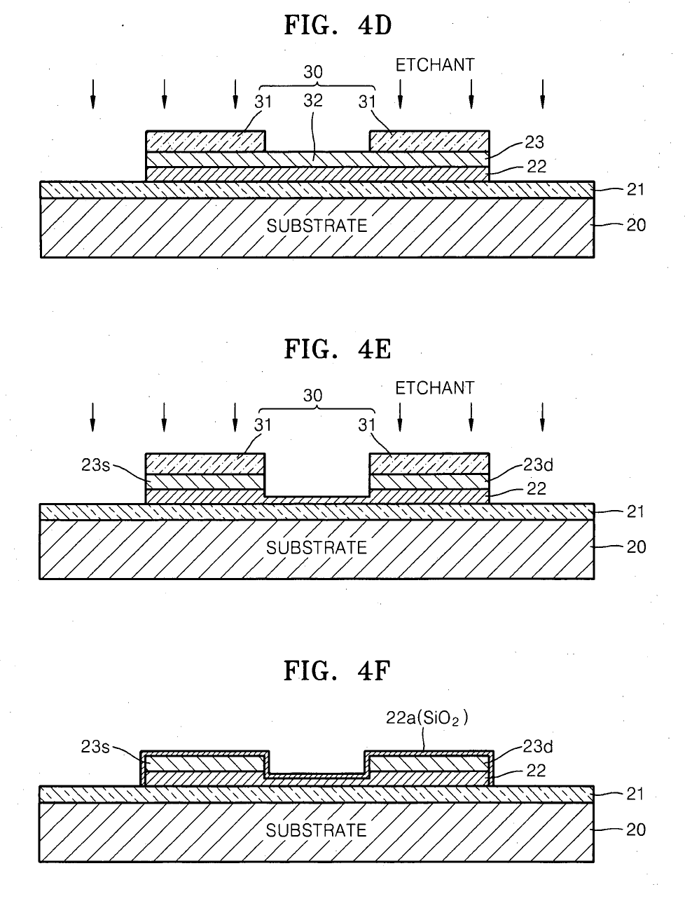

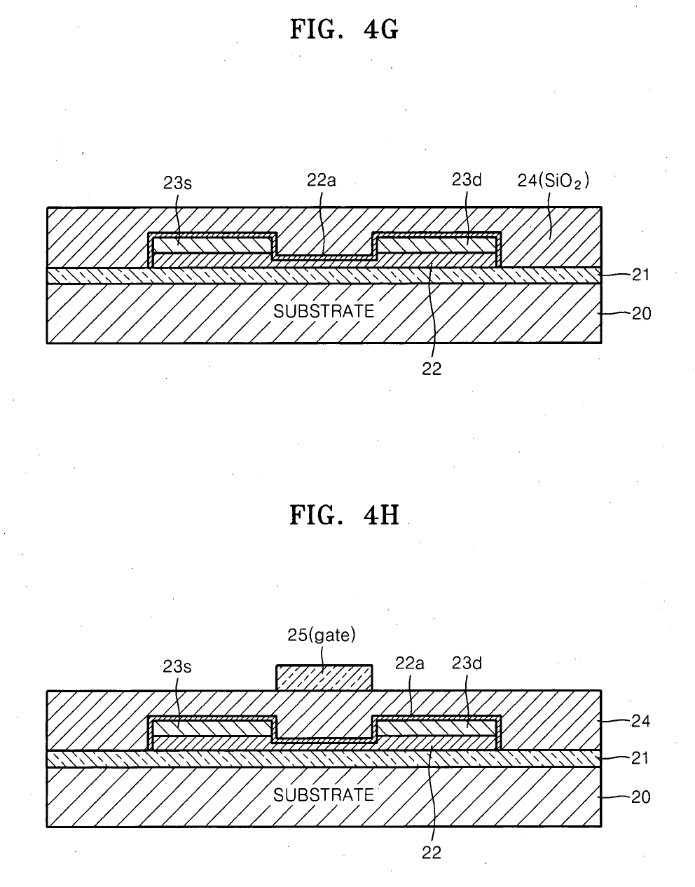

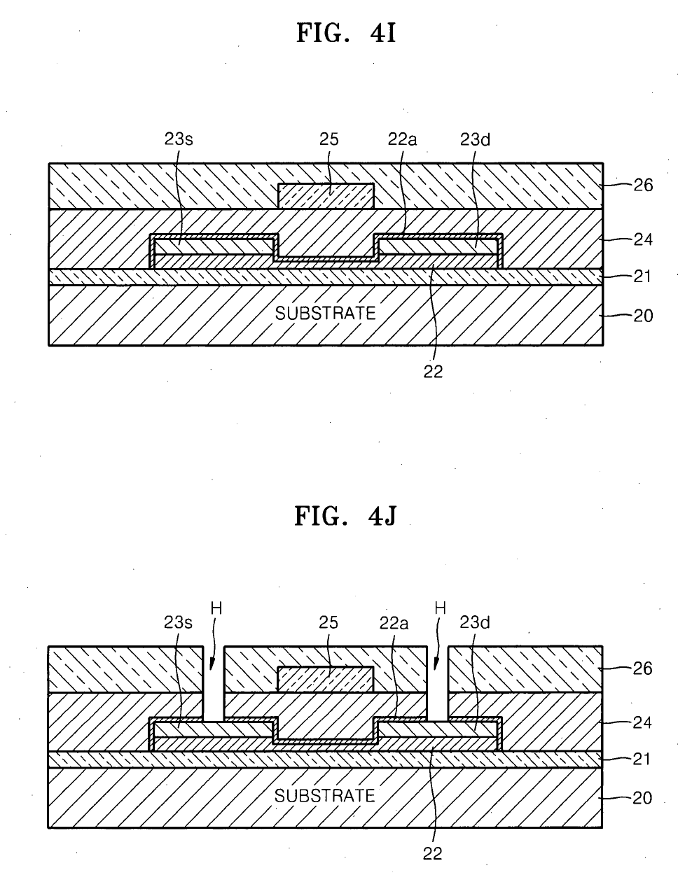

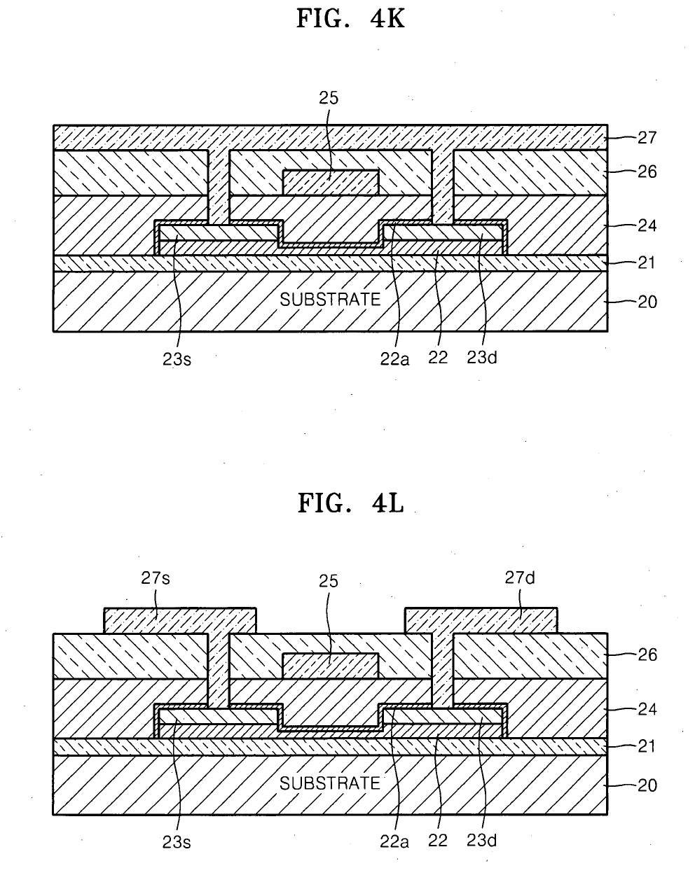

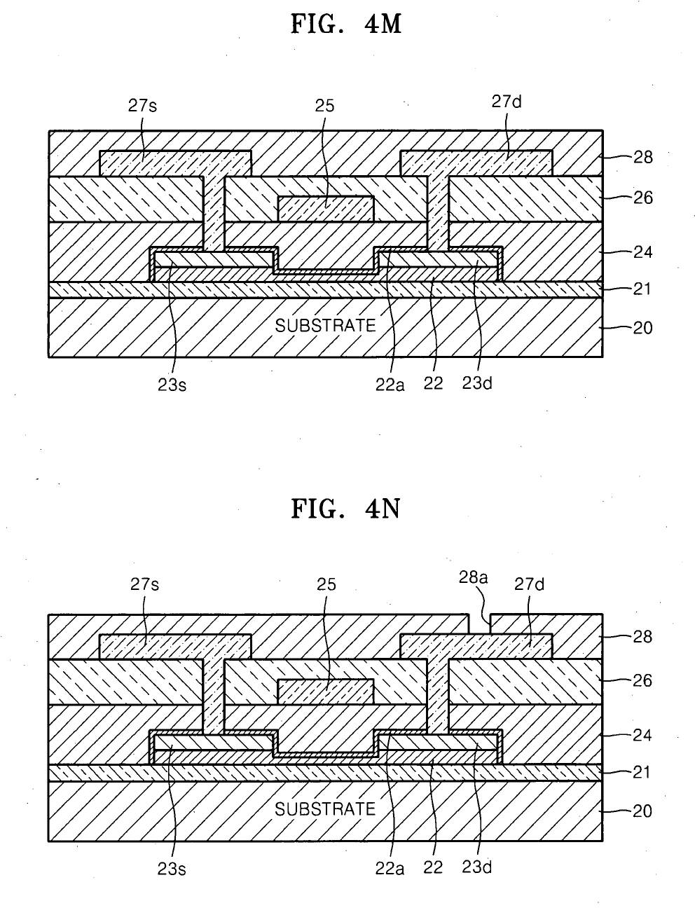

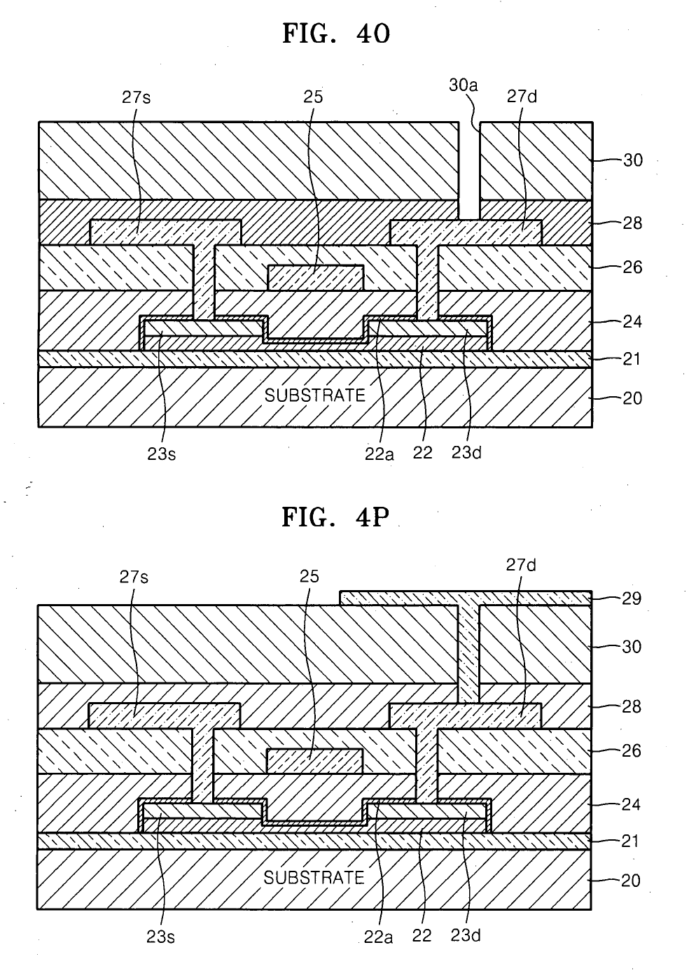

A method of fabricating a TFT according to an example embodiment will now be described in detail with reference to FIGS. 4A through 4P.

As shown in FIG. 4A, silicon oxide (SiO₂) having a thickness between 100 nm and 500 nm, amorphous oxide (a−si) having a thickness between 100 nm and 200 nm, and/or n+ doped amorphous silicon (n+ doped a−Si) having a thickness between 50 nm and 100 nm may be deposited, for example deposited sequentially, on a substrate 20 formed of a plastic or glass to obtain a buffer layer 21, a silicon channel material layer 22′, and/or an ohmic material layer 23. The depositing may be performed using plasma enhanced chemical vapor deposition (PECVD). Solid phase crystallization (SPC) may be performed using rapid thermal annealing (RTA) to polycrystallize the channel material layer 22′ and the ohmic material layer 23. The RTA may be performed at a temperature between 700° C. and 750° C. for about 5 minutes to 20 minutes.

As shown in FIG. 4B, a photoresist mask 30 may be formed on the ohmic material layer 23. The photoresist mask 30 may include thicker first portions 31 corresponding to the source and drain ohmic layers 23s and 23d on both ends of the channel 22 of the above-described TFT and/or a thinner second portion 32 positioned between the first portions 31. The photoresist mask 30 having the first and second portions 31 and 32 having different thicknesses may be obtained by exposing a photoresist using a slit mask or a half tone mask showing a locally different exposure amount or by a different exposure technique. A technique for fabricating a solid photoresist mask according to an exposure amount difference using such a slit mask or a half tone mask is well known in the art and will not be described in detail herein.

As shown in FIG. 4C, portions of the ohmic material layer 23 and/or the channel material layer 22′ which may not be covered with the photoresist mask 30 may be etched. A silicon channel 22 may be formed as a result of patterning the channel material layer 22′ underneath the ohmic material layer 23, and the ohmic material layer 23 may remain, in a semi-processed state, on the silicon channel 22 and may have the same pattern as the silicon channel 22.

As shown in FIG. 4D, the photoresist mask 30 may be ashed in oxygen and plasma atmospheres to remove the second portion 32 of the photoresist mask 30 but leave the first portions 31. The first portions 31 may be ashed and become thinner when the second portion 32 is removed.

As shown in FIG. 4E, a surface of the silicon channel 22 which may not be covered with the first portions 31 of the photoresist mask 30 may be etched to a thinner thickness using an etchant to completely remove remnants of the ohmic material layer 23 remaining on the exposed surface of the silicon channel 22. The photoresist 30 may be stripped and cleaned using hydrogen fluoride (HF).

As shown in FIG. 4F, thermal oxidization may be performed at a higher temperature between 700° C. and 750° C. in an oxygen atmosphere to form an oxide layer 22a on the surface of the silicon channel 22. The oxide layer 22a may be formed on the surface of the silicon channel 22 and/or surfaces of the source and drain ohmic layers 23s and 23d.

As shown in FIG. 4G, a gate insulator 24 may be formed of SiO₂ to a thickness between 50 nm and 100 nm on the resultant stack structure using PECVD.

As shown in FIG. 4H, a gate 25 may be formed on the gate insulator 24. A gate material layer may be deposited and patterned to form the gate 25. The depositing of the gate layer may be performed using a sputtering method, and the patterning of the gate material layer may be performed using a general photolithographic method. The gate 25 may have a single metal layer structure or a multiple metal layer structure, for example, a single metal layer structure of Mo or a multiple metal layer structure of Al and Mo, AlNd and Mo, or Mo, Al, and Mo. A single layer or multiple layer structure of the gate 25 may be generally known and does not limit the scope of example embodiments.

As shown in FIG. 4I, an ILD layer 26 may be formed on the gate insulator 24 to cover the gate 25. The ILD layer 26 may be a SiO₂ layer formed using PECVD.

As shown in FIG. 4J, contact holes H may be formed in the ILD layer 26 and/or the gate insulator 24 so as to reach the surfaces of the source and drain ohmic layers 23s and 23d.

As shown in FIG. 4K, an electrode material layer 27 may be formed on the ILD layer 26. The electrode material layer 27 may fill the contact holes H so as to be electrically connected to the source and drain ohmic layers 23s and 23d. The electrode material layer 27 may be formed of a generally known material, for example, the same material as that of which the gate 25 may be formed.

As shown in FIG. 4L, the electrode material layer 27 may be patterned to obtain a source electrode 27s connected to the source ohmic layer 23s and a drain electrode 27d connected to the drain ohmic layer 23d.

As shown in FIG. 4M, a passivation layer 28 may be formed to cover the source and drain electrodes 27s and 27d. The passivation layer 28 may be a SiNx layer formed using PECVD.

As shown in FIG. 4N, a via hole 28a may be formed in the passivation layer 28 using a general patterning method so as to reach the drain electrode 27d.

As shown in FIG. 40, if a surface of the passivation layer 28 is uneven and is to be planarized, a planar layer 30 may be additionally formed. A via hole 30a may be formed in the planar layer 30 so as to reach the via hole 28a of the passivation layer 28. The via hole 28a of the passivation layer 28 and the via hole 30a of the planar layer 30 may be formed at the same time.

As shown in FIG. 4P, an electrode, for example an electrode of an OLED, e.g., an anode 29, may be formed. The anode 29 may be formed of a transparent conductive material, for example an indium tin oxide (ITO) or an indium zinc oxide (IZO).

An additional process used in manufacturing an OLED display may be performed to obtain a desired display.

As described above, according to example embodiments, a top gate type TFT suitable for an OLED display may be obtained. A conventional top gate type TFT may be polluted by a metal of which source and drain electrodes may be formed during cleaning of an interface, and an interface characteristic between a channel and a gate may be poorer. However, in example embodiments, when a channel may be cleaned, source and drain layers have not yet been formed of a metal. Accordingly, pollution of the top gate type TFT of example embodiments by the metallic material may be reduced.

Ohmic layers may be separated from electrodes. Accordingly, poorer step coverage need not occur and a gate insulator may not be cracked. Even if the gate insulator is cracked, metal electrodes may not be formed underneath the gate insulator. Accordingly, an etchant need not permeate electrodes, and the electrodes may not be dissolved by the etchant.

The channel may be oxidized to reduce an interface trap density so as to maintain a characteristic of the TFT in a higher-quality state. A method of fabricating the top gate type TFT according to example embodiments may be suitable for fabricating the OLED display.

Although example embodiments have been shown and described in this specification and figures, it would be appreciated by those skilled in the art that changes may be made to the illustrated and/or described example embodiments without departing from their principles and spirit, the scope of which is defined by the claims and their equivalents.

What is claimed is:

1. A TFT (thin film transistor) comprising:
a substrate;
a channel on the substrate;
source and drain layers on both ends of the channel;
a gate insulator covering the source and drain ohmic layers and the channel;
a gate on the gate insulator;
an interlayer dielectric (ILD) layer covering the gate; and
source and drain electrodes contacting the source and drain layers through contact holes formed in the ILD layer and the gate insulator.

2. The TFT of claim 1, wherein the source and drain layers are source and drain ohmic layers.

3. The TFT of claim 1, further comprising a passivation layer covering the source and drain electrodes.

4. The TFT of claim 1, further comprising:
an oxide layer on a surface of the channel.

5. The TFT of claim 4, wherein end portions of the channel contacting the source and drain layers are thicker than a central portion of the channel.

6. The TFT of claim 1, wherein end portions of the channel contacting the source and drain layers are thicker than a central portion of the channel.

7. The TFT of claim 1, further comprising a buffer layer between the substrate and the channel.

8. The TFT of claim 3, further comprising an electrode contacting the drain electrode through a via hole formed in the passivation layer.

9. A method of fabricating a TFT, comprising:
forming a silicon channel material layer and a silicon ohmic material layer on a substrate;
patterning the silicon channel material layer and the silicon ohmic material layer to form a silicon channel and source and drain ohmic layers contacting ends of the silicon channel;
forming a gate insulator covering the source and drain ohmic layers;
forming a gate corresponding to the silicon channel on the gate insulator;
forming an interlayer dielectric (ILD) layer on the gate insulator to cover the gate;
forming contact holes in the ILD layer and the gate insulator on the source and drain ohmic layers;
forming source and drain electrodes contacting the source and drain ohmic layers respectively through the contact holes; and
forming a passivation layer covering the source and drain electrodes on the ILD layer.

10. The method of claim 9, wherein forming the silicon channel material layer and the silicon ohmic material layer on the substrate is done sequentially.

11. The method of claim 9, wherein patterning the silicon channel material layer and the silicon ohmic material layer includes:
forming a photoresist mask on the silicon ohmic material layer, the photoresist mask including first portions corresponding to the source and drain ohmic layers and a second portion positioned between the source and drain ohmic layers, wherein the second portion is thinner than the first portions;
removing portions of the silicon ohmic material layer and a portion of the silicon channel material layer that are not covered with the photoresist mask;
ashing an entire surface of the photoresist mask at least by a thickness corresponding to the second portion of the photoresist mask to remove the second portion of the photoresist mask;
removing a portion of the silicon ohmic material layer that is not covered with the first portions of the photoresist mask; and
removing the photoresist mask.

12. The method of claim 11, wherein the photoresist mask including the first and second portions is formed using a photolithographic method using one of a slit mask and a half tone mask.

13. The method of claim 12, further comprising polycrystallizing the silicon channel material layer using solid phase crystallization (SPC) before the silicon channel and the source and drain ohmic layers contacting ends of the silicon channel are formed.

14. The method of claim 13, wherein the solid phase crystallization (SPC) is performed using rapid thermal annealing (RTA).

15. The method of claim 9, further comprising polycrystallizing the silicon channel material layer using solid phase crystallization (SPC) before the silicon channel and the source and drain ohmic layers contacting ends of the silicon channel are formed.

16. The method of claim 15, wherein the solid phase crystallization (SPC) is performed using rapid thermal annealing (RTA).

17. The method of claim 16, further comprising forming an oxide layer on a surface of the silicon channel using thermal oxidization after the source and drain ohmic layers are formed.

18. The method of claim 15, further comprising forming an oxide layer on a surface of the silicon channel using thermal oxidization after the source and drain ohmic layers are formed.

19. The method of claim 9, further comprising forming an oxide layer on a surface of the silicon channel using thermal oxidization after the source and drain ohmic layers are formed.

20. The method of claim 13, further comprising forming an oxide layer on a surface of the silicon channel using thermal oxidization after the source and drain ohmic layers are formed.

21. The method of claim 14, further comprising forming an oxide layer on a surface of the silicon channel using thermal oxidization after the source and drain ohmic layers are formed.
